(19) United States
(12) Patent Application Publication
(10) Pub. No.: US 2026/0371968 A1
(43) Pub. Date: Nov. 19, 2026

(54) METHOD OF MANUFACTURING A SEMICONDUCTOR DEVICE

(71) Applicant: Taiwan Semiconductor Manufacturing Company, Ltd., Hsinchu (TW)

(72) Inventors: Wei-Chao CHIU, Hsinchu (TW); Yong-Jin LIOU, Tainan (TW); Feng-Jia SHIU, Jhudong (TW); Ching-Sen KUO, Taipei (TW); Chun-Wei CHANG, Tainan (TW)

(73) Assignee: Taiwan Semiconductor Manufacturing Company, Ltd., Hsinchu (TW)

(21) Appl. No.: 19/751,624

(22) Filed: Jul. 23, 2026

Related U.S. Application Data
(62) Division of application No. 18/110,778, filed on Feb. 16, 2023.

(51) Int. Cl. H10P 50/00; H10F 39/00; H10P 30/22; H10P 74/20; H10P 76/20

(52) U.S. Cl. CPC H10P 50/695; H10F 39/014; H10P 30/22; H10P 50/692; H10P 74/203; H10P 76/2042

(57) ABSTRACT

A method of fabricating a semiconductor device includes determining a concentration of a byproduct in a photoresist composition. A photoresist layer is formed over a substrate using the photoresist composition when the concentration of the byproduct is below a threshold value. A photoresist pattern is formed in the photoresist layer exposing a portion of the substrate, and an operation is performed on the exposed portion of the substrate.

### CROSS-REFERENCE TO RELATED APPLICATIONS

This application is a divisional of U.S. patent application Ser. No. 18/110,778, filed Feb. 16, 2023, the entire disclosure of which is hereby incorporated by reference herein.

### BACKGROUND

Image sensor devices are widely used in various imaging applications and products, such as digital still cameras or mobile phone camera applications. These devices utilize an array of sensor elements (pixels) in a substrate. The pixels may be photodiodes or other photosensitive elements that are adapted to absorb light projected toward the substrate and convert the sensed light into electrical signals. To receive more light, it is advantageous to increase the number of the pixels in the image sensor devices.

The ever-shrinking geometry size brings challenges to image sensor device fabrication. For example, the fabrication process may require photoresist masks with high an aspect ratio to produce pixels that are micron or sub-micron in size. However, photoresist masks with ultrahigh aspect ratio are more prone to the effects of capillary forces. These effects are exacerbated as the aspect ratio of the mask increase and/or as the pitch decreases. As a result, photoresist masks may collapse, for example, due to the pulling effect of capillary forces between adjacent photoresist masks. In addition, photoresist masks with an ultrahigh aspect ratio may suffer from a T-topping profile, which can cause etch residues to form in subsequently formed trenches in the substrate being etched.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a portion of an image sensor device in accordance with an embodiment of the disclosure.

FIG. 2 illustrates a schematic view of a lithography process performed to transfer an image onto the first photoresist layer on device substrate in accordance with an embodiment of the disclosure.

FIG. 3 illustrates a selective exposure of a photoresist layer in accordance with an embodiment of the disclosure.

FIG. 4 illustrates a photoresist development operation in accordance with an embodiment of the disclosure.

FIG. 5 illustrates a patterned photoresist layer in accordance with an embodiment of the disclosure.

FIG. 6 illustrates a plan (top) view of a portion of an image sensor device showing a pattern has been transferred to the first photoresist layer to form first photoresist columns on the front side of the device substrate in accordance with an embodiment of the disclosure.

FIG. 7 illustrates a cross-sectional view of the image sensor device taken along line A-A of FIG. 6.

FIG. 8 illustrates the formation of tertiary amine oxides from a quencher in a photoresist composition.

FIGS. 9A and 9B illustrate the relationship between the change in photoresist trench widths and the concentration of N-oxides in the photoresist composition.

FIG. 10 illustrates a detail of a photoresist pattern formed in accordance with an embodiment of the disclosure.

FIG. 11 illustrates a cross-sectional view of the device substrate after a first ion implantation process in accordance with an embodiment of the disclosure.

FIG. 12 illustrates a cross-sectional view of a portion of the image sensor device after the first photoresist layer has been removed in accordance with an embodiment of the disclosure.

FIG. 13 illustrates a cross-sectional view of a second photoresist layer formed over the front side of the device substrate in accordance with an embodiment of the disclosure.

FIG. 14 illustrates a plan (top) view of a second photomask having a second pattern in accordance with an embodiment of the disclosure.

FIG. 15 illustrates a cross-sectional view of a portion of an image sensor device having a patterned second photoresist layer on the device substrate in accordance with an embodiment of the disclosure.

FIG. 16 illustrates a cross-sectional view of a portion of an image sensor device showing first and second isolation regions in accordance with an embodiment of the disclosure.

FIG. 17 illustrates a cross-sectional view of an image sensor device showing pixel regions in the device substrate in accordance with an embodiment of the disclosure.

FIG. 18 illustrates a cross-sectional view of an image sensor device showing a plurality of pixels formed in the pixel regions in accordance with an embodiment of the disclosure.

FIG. 19 illustrates a cross-sectional view of the image sensor device showing an interconnect structure over the front side of the device substrate in accordance with an embodiment of the disclosure.

FIG. 20 illustrates an etching operation in accordance with an embodiment of the disclosure.

FIG. 21 illustrates an etching operation in accordance with an embodiment of the disclosure.

FIG. 22 illustrates an etched substrate in accordance with an embodiment of the disclosure.

FIG. 23 illustrates an etching operation in accordance with an embodiment of the disclosure.

FIG. 24 illustrates an etched substrate in accordance with an embodiment of the disclosure.

FIG. 25 is a flowchart of a method of manufacturing a semiconductor device according to an embodiment of the disclosure.

FIG. 26 is a flowchart of a method of manufacturing a semiconductor device according to an embodiment of the disclosure.

FIG. 27 is a flowchart of a method of manufacturing a complementary metal-oxide-semiconductor image sensor according to an embodiment of the disclosure.

FIGS. 28A and 28B show an embodiment of a controller according to embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication processes, there may be one or more additional operations in/between the described operations, and the order of operations may be changed. Materials, configurations, dimensions, processes and/or operations as explained with respect to one embodiment may be employed in the other embodiments, and the detailed description thereon may be omitted. Source/drain region(s) may refer to a source or a drain, individually or collectively dependent upon the context.

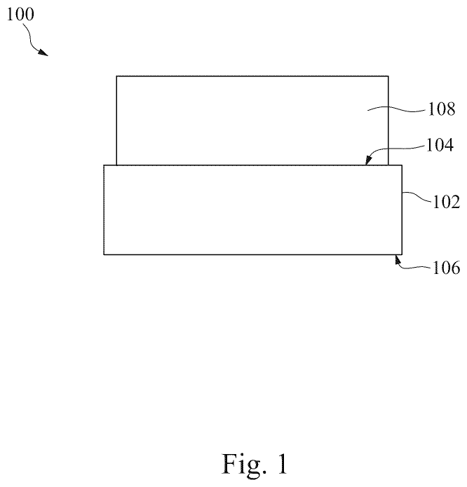

FIG. 1 illustrates a schematic cross-sectional view of a portion of an image sensor device 100 in accordance with an embodiment. The image sensor device 100 may be used in various electronic devices for capturing images, such as cameras, cellular telephones, personal digital assistants, computers, etc. Examples of such an image sensor device include a complementary metal-oxide semiconductor (CMOS) image sensor (CIS) device, a charged-coupled device (CCD), an active-pixel sensor (APS) device, or a passive-pixel sensor device. In one embodiment, the image sensor device 100 is a backside illuminated (BSI) image sensor device. While the present disclosure is described with respect to backside illuminated image sensor devices, the embodiments of the disclosure may also be applied to a front side illuminated (FSI) image sensor device. The image sensor device 100 may be a CIS and includes a device substrate 102. The device substrate 102 is, for example, a bulk substrate of silicon, an epitaxial layer over a silicon substrate, a semiconductor wafer, a silicon germanium substrate, or a silicon-on-insulator (SOI) substrate. Other semiconductor materials including group III, group IV, and group V elements may be used in some embodiments. The device substrate 102 may be undoped in some embodiments. In some other embodiments, the device substrate 102 is doped with a p-type dopant such as boron (i.e., a p-type substrate) or an n-type dopant such as phosphorous or arsenic (i.e., an n-type substrate). The device substrate 102 could optionally include a compound semiconductor and/or an alloy semiconductor. In some embodiments, the device substrate 102 could include an epitaxial layer, which may be strained for performance enhancement.

The device substrate 102 has a front side (also referred to as a front surface) 104 and a back side (also referred to as a back surface) 106 opposing the front side 104. For a BSI image sensor device, such as the image sensor device 100, light or radiation is incident upon the back side 106 (after a substrate thinning process) and enters the remaining device substrate 102 through the back side 106. The front side 104 is an active surface on which circuit designs, such as transistor, contact, and interconnection features, are formed to provide external communication with the pixels in the pixel regions.

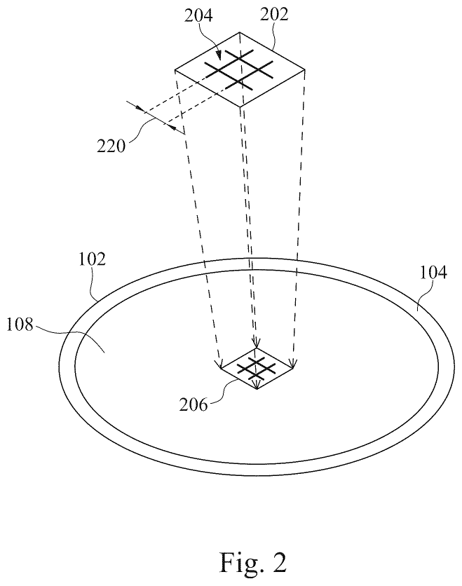

A method of manufacturing a semiconductor device, such as a CIS, is described in FIGS. 2-19. A first photoresist layer 108 is formed over the front side 104 of the device substrate 102. The first photoresist layer 108 may be formed by depositing (e.g., spin-coating) a photoresist film over the front side 104 of the device substrate 102 and thereafter patterning the photoresist film in a first photolithography process, which may involve one or more processes such as exposure, post-exposure bake, developing, etc. The first photolithography process uses a photolithography apparatus to pattern the first photoresist layer 108. The photolithography apparatus includes a radiation source to provide actinic radiation to expose the photoresist layer, a lens system to project the actinic radiation onto the photoresist layer, and a mask stage having a scan function. The radiation source may be a suitable light source such as an ultraviolet (UV), deep ultraviolet (DUV), or extreme ultraviolet (EUV) source. For example, the radiation source may include, but is not limited to, a deep ultraviolet laser, such as a krypton fluoride (KrF) excimer laser with wavelength of 248 nm, an argon fluoride (ArF) excimer laser with a wavelength of 193 nm, and fluoride (F₂) excimer laser with a wavelength of 157 nm; an ultraviolet mercury lamp having a wavelength of 436 nm or 365 nm; electron beam, or other light sources having a wavelength below approximately 100 nm. The lens system may include one or more illumination modules designed to direct radiation beams from the radiation source onto a photomask. The mask stage is operable to secure the photomask and manipulate the photomask in transitional and/or rotational modes. The lithography apparatus also includes a substrate stage for holding and manipulating a substrate to be patterned in transitional and/or rotational modes during the first lithography process. It is understood that the manipulation of the substrate is considered relative to the photomask so that one or both of the mask stage and substrate stage can move to achieve the desired manipulation. An alignment device can be used to align the photomask and the substrate.

The photoresist layer 108 is formed by depositing a photoresist composition over the substrate 102 or a target layer on the substrate. The photoresist composition includes a photoactive compound (PAC), a polymer, and a solvent. In some embodiments, the photoresist composition further includes a quencher and a surfactant. In some embodiments, the photoresist layer 208 uses a chemical amplification (CA) photoresist material. In some embodiments, the CA photoresist material is a positive tone photoresist and includes a polymer material that becomes soluble to a developer after the polymeric material is reacted with an acid. In another embodiment, the CA photoresist material is negative tone photoresist and includes a polymer material that becomes insoluble to a developer, such as a base solution, after the polymer is reacted with acid. In yet another embodiment, the CA photoresist material includes a polymer material that changes its polarity after the polymer is reacted with acid so that either exposed portions or unexposed portions will be removed during a developing operation, depending on the type of developer (organic solvent or aqueous solvent). In some embodiments, the CA photoresist composition includes a photoacid generator (PAG) as the photoactive compound. In some embodiments, the photoresist composition includes other additives, such as sensitizers. The polymer material in a CA resist material may further include an acid-labile group.

Whether a resist is a positive tone or negative tone may depend on the type of developer used to develop the resist. For example, some positive tone photoresists provide a positive pattern, (i.e.—the exposed regions are removed by the developer), when the developer is an aqueous-based developer, such as a tetramethylammonium hydroxide (TMAH) solution. On the other hand, the same photoresist provides a negative pattern (i.e. the unexposed regions are removed by the developer) when the developer is an organic solvent. Further, in some negative tone photoresists developed with the TMAH solution, the unexposed regions of the photoresist are removed by the TMAH, and the exposed regions of the photoresist that undergo cross-linking upon exposure to actinic radiation remain on the substrate after development.

In some embodiments, the polymer in the photoresist composition includes a hydrocarbon structure (such as an alicyclic hydrocarbon structure) that contains one or more groups that will decompose (e.g., acid labile groups) or otherwise react when mixed with acids, bases, or free radicals generated by the PACs (as further described below). In some embodiments, the hydrocarbon structure includes a repeating unit that forms a skeletal backbone of the polymer. This repeating unit may include acrylic esters, methacrylic esters, crotonic esters, vinyl esters, maleic diesters, fumaric diesters, itaconic diesters, (meth)acrylonitrile, (meth)acrylamides, styrenes, vinyl ethers, combinations of these, or the like.

Specific structures that are utilized for the repeating unit of the hydrocarbon structure in some embodiments, include one or more of methyl acrylate, ethyl acrylate, n-propyl acrylate, isopropyl acrylate, n-butyl acrylate, isobutyl acrylate, tert-butyl acrylate, n-hexyl acrylate, 2-ethylhexyl acrylate, acetoxyethyl acrylate, phenyl acrylate, 2-hydroxyethyl acrylate, 2-methoxyethyl acrylate, 2-ethoxyethyl acrylate, 2-(2-methoxyethoxy)ethyl acrylate, cyclohexyl acrylate, benzyl acrylate, 2-alkyl-2-adamantyl (meth)acrylate or dialkyl(1-adamantyl)methyl (meth)acrylate, methyl methacrylate, ethyl methacrylate, n-propyl methacrylate, isopropyl methacrylate, n-butyl methacrylate, isobutyl methacrylate, tert-butyl methacrylate, n-hexyl methacrylate, 2-ethylhexyl methacrylate, acetoxyethyl methacrylate, phenyl methacrylate, 2-hydroxyethyl methacrylate, 2-methoxyethyl methacrylate, 2-ethoxyethyl methacrylate, 2-(2-methoxyethoxy)ethyl methacrylate, cyclohexyl methacrylate, benzyl methacrylate, 3-chloro-2-hydroxypropyl methacrylate, 3-acetoxy-2-hydroxypropyl methacrylate, 3-chloroacetoxy-2-hydroxypropyl methacrylate, butyl crotonate, hexyl crotonate, or the like. Examples of the vinyl esters include vinyl acetate, vinyl propionate, vinyl butylate, vinyl methoxyacetate, vinyl benzoate, dimethyl maleate, diethyl maleate, dibutyl maleate, dimethyl fumarate, diethyl fumarate, dibutyl fumarate, dimethyl itaconate, diethyl itaconate, dibutyl itaconate, acrylamide, methyl acrylamide, ethyl acrylamide, propyl acrylamide, n-butyl acrylamide, tert-butyl acrylamide, cyclohexyl acrylamide, 2-methoxyethyl acrylamide, dimethyl acrylamide, diethyl acrylamide, phenyl acrylamide, benzyl acrylamide, methacrylamide, methyl methacrylamide, ethyl methacrylamide, propyl methacrylamide, n-butyl methacrylamide, tert-butyl methacrylamide, cyclohexyl methacrylamide, 2-methoxyethyl methacrylamide, dimethyl methacrylamide, diethyl methacrylamide, phenyl methacrylamide, benzyl methacrylamide, methyl vinyl ether, butyl vinyl ether, hexyl vinyl ether, methoxyethyl vinyl ether, dimethylaminoethyl vinyl ether, or the like. Examples of styrenes include styrene, methyl styrene, dimethyl styrene, trimethyl styrene, ethyl styrene, isopropyl styrene, butyl styrene, methoxy styrene, butoxy styrene, acetoxy styrene, chloro styrene, dichloro styrene, bromo styrene, vinyl methyl benzoate, α-methyl styrene, maleimide, vinylpyridine, vinylpyrrolidone, vinylcarbazole, combinations of these, or the like.

In some embodiments, the repeating unit of the hydrocarbon structure also has either a monocyclic or a polycyclic hydrocarbon structure substituted into it, or the monocyclic or polycyclic hydrocarbon structure is the repeating unit, in order to form an alicyclic hydrocarbon structure. Specific examples of monocyclic structures in some embodiments include bicycloalkane, tricycloalkane, tetracycloalkane, cyclopentane, cyclohexane, or the like. Specific examples of polycyclic structures in some embodiments include adamantane, norbornane, isobornane, tricyclodecane, tetracyclododecane, or the like.

The group which will decompose, otherwise known as a leaving group or, in some embodiments in which the PAC is a photoacid generator, an acid labile group, is attached to the hydrocarbon structure so that, it will react with the acids/bases/free radicals generated by the PACs during exposure. In some embodiments, the group which will decompose is a carboxylic acid group, a fluorinated alcohol group, a phenolic alcohol group, a sulfonic group, a sulfonamide group, a sulfonylimido group, an (alkylsulfonyl) (alkylcarbonyl)methylene group, an (alkylsulfonyl)(alkyl-carbonyl)imido group, a bis(alkylcarbonyl)methylene group, a bis(alkylcarbonyl)imido group, a bis(alkylsylfonyl)methylene group, a bis(alkylsulfonyl)imido group, a tris(alkylcarbonyl methylene group, a tris(alkylsulfonyl)methylene group, combinations of these, or the like. Specific groups that are used for the fluorinated alcohol group include fluorinated hydroxyalkyl groups, such as a hexafluoroisopropanol group in some embodiments. Specific groups that are used for the carboxylic acid group include acrylic acid groups, methacrylic acid groups, or the like.

In some embodiments, the polymer also includes other groups attached to the hydrocarbon structure that help to improve a variety of properties of the polymerizable resin. In some embodiments, the lactone groups include rings having five to seven members are attached to the polymer although any suitable lactone structure may alternatively be used for the lactone group.

In some embodiments, the polymer includes groups that can assist in increasing the adhesiveness of the photoresist layer to underlying structures (e.g., substrate). Polar groups may be used to help increase the adhesiveness. Suitable polar groups include hydroxyl groups, cyano groups, or the like, although any suitable polar group may, alternatively, be used.

Additionally, some embodiments of the photoresist include one or more photoactive compounds (PACs). The PACs are photoactive components, such as photoacid generators, photobase generators, free-radical generators, or the like. The PACs may be positive-acting or negative-acting. In some embodiments in which the PACs are a photoacid generator, the PACs include halogenated triazines, onium salts, diazonium salts, aromatic diazonium salts, phosphonium salts, sulfonium salts, iodonium salts, imide sulfonate, oxime sulfonate, diazodisulfone, disulfone, o-nitrobenzylsulfonate, sulfonated esters, halogenated sulfonyloxy dicarboximides, diazodisulfones, α-cyanooxyamine-sulfonates, imidesulfonates, ketodiazosulfones, sulfonyldiazoesters, 1,2-di(arylsulfonyl)hydrazines, nitrobenzyl esters, and the s-triazine derivatives, combinations of these, or the like.

Specific examples of photoacid generators include α-(trifluoromethylsulfonyloxy)-bicyclo[2.2.1]hept-5-ene-2,3-dicarb-o-ximide (MDT), N-hydroxy-naphthalimide (DDSN), benzoin tosylate, t-butylphenyl-α-(p-toluenesulfonyloxy)-acetate and t-butyl-α-(p-toluenesulfonyloxy)-acetate, triarylsulfonium and diaryliodonium hexafluoroantimonates, hexafluoroarsenates, trifluoromethanesulfonates, iodonium perfluorooctanesulfonate, N-camphorsulfonyloxynaphthalimide, N-pentafluorophenylsulfonyloxynaphthalimide, ionic iodonium sulfonates such as diaryl iodonium (alkyl or aryl)sulfonate and bis-(di-t-butylphenyl)iodonium camphanylsulfonate, perfluoroalkanesulfonates such as perfluoropentanesulfonate, perfluorooctanesulfonate, perfluoromethanesulfonate, aryl (e.g., phenyl or benzyl)triflates such as triphenylsulfonium triflate or bis-(t-butylphenyl)iodonium triflate; pyrogallol derivatives (e.g., trimesylate of pyrogallol), trifluoromethanesulfonate esters of hydroxyimides, α, α′-bis-sulfonyl-diazomethanes, sulfonate esters of nitro-substituted benzyl alcohols, naphthoquinone-4-diazides, alkyl disulfones, or the like.

In some embodiments in which the PACs are free-radical generators, the PACs include n-phenylglycine; aromatic ketones, including benzophenone, N, N′-tetramethyl-4,4′-diaminobenzophenone, N, N′-tetraethyl-4,4′-diaminobenzophenone, 4-methoxy-4′-dimethylaminobenzo-phenone, 3,3′-dimethyl-4-methoxybenzophenone, p,p′-bis(dimethylamino)benzo-phenone, p,p′-bis(diethylamino)-benzophenone; anthraquinone, 2-ethylanthraquinone; naphthaquinone; and phenanthraquinone; benzoins including benzoin, benzoinmethylether, benzoinisopropylether, benzoin-n-butylether, benzoin-phenylether, methylbenzoin and ethylbenzoin; benzyl derivatives, including dibenzyl, benzyldiphenyldisulfide, and benzyldimethylketal; acridine derivatives, including 9-phenylacridine, and 1,7-bis(9-acridinyl)heptane; thioxanthones, including 2-chlorothioxanthone, 2-methylthioxanthone, 2,4-diethylthioxanthone, 2,4-dimethylthioxanthone, and 2-isopropylthioxanthone; acetophenones, including 1,1-dichloroacetophenone, p-t-butyldichloro-acetophenone, 2,2-diethoxyacetophenone, 2,2-dimethoxy-2-phenylacetophenone, and 2,2-dichloro-4-phenoxyacetophenone; 2,4,5-triarylimidazole dimers, including 2-(o-chlorophenyl)-4,5-diphenylimidazole dimer, 2-(o-chlorophenyl)-4,5-di-(m-methoxyphenyl) imidazole dimer, 2-(o-fluorophenyl)-4,5-diphenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer, 2-(2,4-dimethoxyphenyl)-4,5-diphenylimidazole dimer and 2-(p-methylmercaptophenyl)-4,5-diphenylimidazole dimmer; combinations of these, or the like.

In some embodiments in which the PACs are photobase generators, the PACs includes quaternary ammonium dithiocarbamates, α aminoketones, oxime-urethane containing molecules such as dibenzophenoneoxime hexamethylene diurethan, ammonium tetraorganylborate salts, and N-(2-nitrobenzyloxycarbonyl)cyclic amines, combinations of these, or the like.

As one of ordinary skill in the art will recognize, the chemical compounds listed herein are merely intended as illustrated examples of the PACs and are not intended to limit the embodiments to only those PACs specifically described. Rather, any suitable PAC may be used, and all such PACs are fully intended to be included within the scope of the present embodiments. In some embodiments, the photoresist composition includes about 1 wt. % to about 10 wt. % of a photoactive compound (PAC) based on the total weight of the PAC and the polymer.

A quencher is added to embodiments of the photoresist composition to inhibit diffusion of the generated acids/bases/free radicals within the photoresist. The quencher improves the resist pattern configuration as well as the stability of the photoresist over time. In an embodiment, the quencher is an amine, such as a secondary lower aliphatic amine, a tertiary lower aliphatic amine, or the like. Examples of suitable amines include trimethylamine, diethylamine, triethylamine, di-n-propylamine, tri-n-propylamine, tripentylamine, diethanolamine, and triethanolamine, alkanolamine, combinations thereof, or the like.

For example, some embodiments of the photoresist also includes surfactants in order to help improve the ability of the photoresist to coat the surface on which it is applied. In some embodiments, the surfactants include nonionic surfactants, polymers having fluorinated aliphatic groups, surfactants that contain at least one fluorine atom and/or at least one silicon atom, polyoxyethylene alkyl ethers, polyoxyethylene alkyl aryl ethers, polyoxyethylene-polyoxypropylene block copolymers, sorbitan fatty acid esters, and polyoxyethylene sorbitan fatty acid esters.

Examples of surfactants in photoresist compositions according to embodiments of the disclosure include polyoxyethylene lauryl ether, polyoxyethylene stearyl ether, polyoxyethylene cetyl ether, polyoxyethylene oleyl ether, polyoxyethylene octyl phenol ether, polyoxyethylene nonyl phenol ether, sorbitan monolaurate, sorbitan monopalmitate, sorbitan monostearate, sorbitan monooleate, sorbitan trioleate, sorbitan tristearate, polyoxyethylene sorbitan monolaurate, polyoxyethylene sorbitan monopalmitate, polyoxyethylene sorbitan monostearate, polyoxyethylene sorbitan trioleate, polyoxyethylene sorbitan tristearate, polyethylene glycol distearate, polyethylene glycol dilaurate, polyethylene glycol dilaurate, polyethylene glycol, polypropylene glycol, polyoxyethylenestearyl ether, polyoxyethylene cetyl ether, fluorine containing cationic surfactants, fluorine containing nonionic surfactants, fluorine containing anionic surfactants, cationic surfactants and anionic surfactants, polyethylene glycol, polypropylene glycol, polyoxyethylene cetyl ether, combinations thereof, or the like.

The solvent in the photoresist composition can be any suitable solvent. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), and 2-heptanone (MAK).

The photoresist layer 108 is formed by spin-coating in some embodiments. After the photoresist layer 108 is formed over the substrate, it is heated in pre-exposure baking operation to dry the photoresist layer 108 at a temperature of about 40 °C to about 120 °C in some embodiments.

FIG. 2 illustrates a diagrammatic view of a first photolithography process forming an image onto the first photoresist layer 108 on the substrate 102 in accordance with an embodiment. For simplicity, FIG. 2 only shows a portion of the first photoresist layer 108 being imaged. During the first lithography process, a photomask, such as a first photomask 202 with a first pattern 204 shown in FIG. 2, is loaded onto a mask stage, and the substrate 102 is loaded onto a substrate stage. The first pattern 204 may have various features such as lines, holes, grids, or any desired shape such as polygons, depending on the features to be formed in the first photoresist layer 108. In one embodiment, the first pattern 204 has a grid-like pattern. The grid-like pattern may be composed of repeating features, for example two pluralities of parallel lines, wherein the lines belonging to one of the pluralities are arranged transverse to the lines belonging to the other plurality to form a plurality of squares. An actinic radiation beam may scan over the first photomask 202. The features of the first pattern 204 allow the actinic radiation beam to pass through and expose a field 206 of the photoresist layer 108 on the substrate 102. The field 206 may define a die (or chip). In one embodiment, the field 206 contains one or more pixel array regions. As such, the first pattern 204 is transferred onto the first photoresist layer 108 at the exposure field 206. The photolithography apparatus then steps the device substrate 102 to a next field (e.g., one scanning field) to expose another field. This step-and-scan process is performed until the entire photoresist layer 108 is exposed with the first pattern 204. The actinic radiation causes a chemical reaction in the exposed portions of the photoresist layer 108 so that it becomes soluble in a developer and is subsequently removed when a developer is applied to the photoresist layer 108.

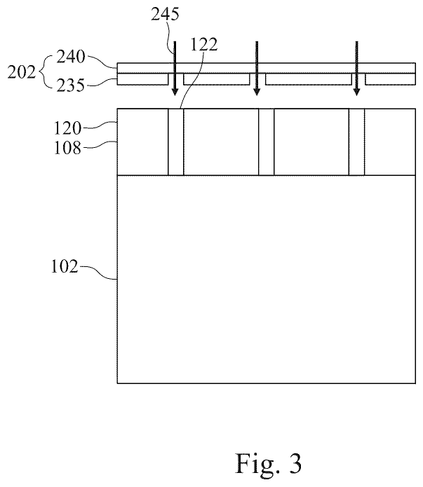

As shown in FIG. 3, the actinic radiation 245 passes through the photomask 202 before irradiating the photoresist layer 108 in some embodiments to form a latent pattern having actinic radiation exposed regions 122 and actinic radiation unexposed regions 120. The photomask has a pattern to be replicated in the photoresist layer 108. The pattern is formed by an opaque pattern 235 on the photomask substrate 240, in some embodiments. The opaque pattern 235 may be formed by a material opaque to ultraviolet radiation, such as chromium, while the photomask substrate 240 is formed of a material that is transparent to ultraviolet radiation, such as fused quartz.

In some embodiments, the exposure of the photoresist layer 108 uses an immersion lithography technique. In such a technique, an immersion medium (not shown) is placed between the final optics and the photoresist layer, and the exposure radiation passes through the immersion medium.

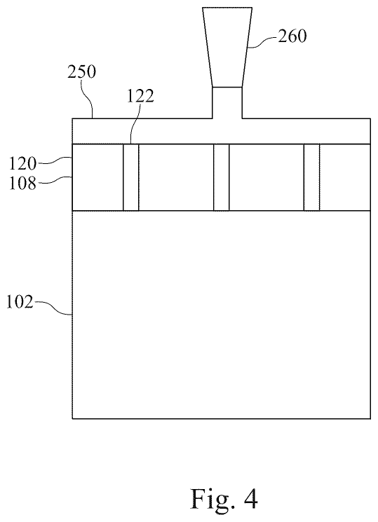

Development is subsequently performed using a solvent, as shown in FIG. 4. In some embodiments where positive tone development is desired, a positive tone developer such as a basic aqueous solution is dispensed from a dispenser 260 and used to remove regions 122 of the photoresist layer exposed to the actinic radiation. In some embodiments, the positive tone developer 250 includes one or more selected from tetramethylammonium hydroxide (TMAH), tetrabutylammonium hydroxide, sodium hydroxide, potassium hydroxide, sodium carbonate, sodium bicarbonate, sodium silicate, sodium metasilicate, aqueous ammonia, monomethylamine, dimethylamine, trimethylamine, monoethylamine, diethylamine, triethylamine, monoisopropylamine, diisopropylamine, triisopropylamine, monobutylamine, dibutylamine, monoethanolamine, diethanolamine, triethanolamine, dimethylaminoethanol, diethylaminoethanol, ammonia, caustic soda, caustic potash, sodium metasilicate, potassium metasilicate, sodium carbonate, tetraethylammonium hydroxide, combinations of these, or the like.

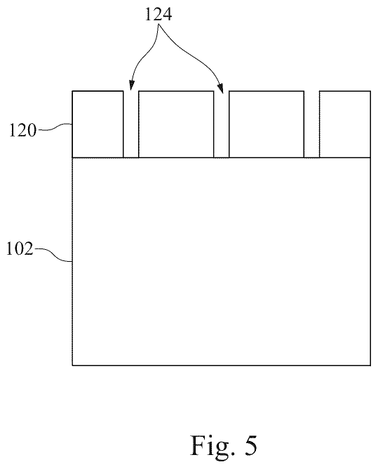

During the development process, the developer 250 dissolves the radiation-exposed regions 122 of the photoresist layer producing trenches 124, exposing the surface of the substrate 102, as shown in FIG. 5, and leaving behind well-defined unexposed photoresist layer regions 120 in some embodiments.

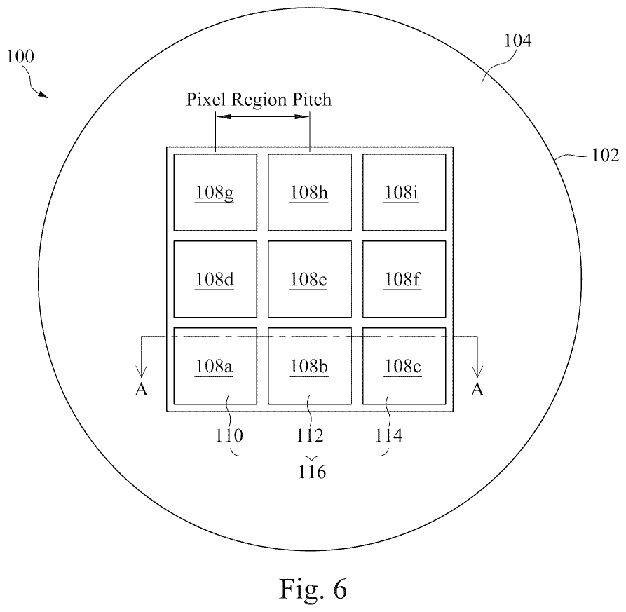

FIG. 6 illustrates a plan (top) view of a portion of the image sensor device 100 showing first photoresist columns 108a-108i on the front side 104 of the device substrate 102 formed by a photolithography process in accordance with an embodiment of the disclosure. It should be understood that nine first photoresist columns 108a-108i are shown here for illustration purposes only. The first photoresist layer 108 may include any numbers of first photoresist columns depending on the requirements for the application. For simplicity, three photoresist columns 108a-108c of the first photoresist layer 108 will be discussed herein.

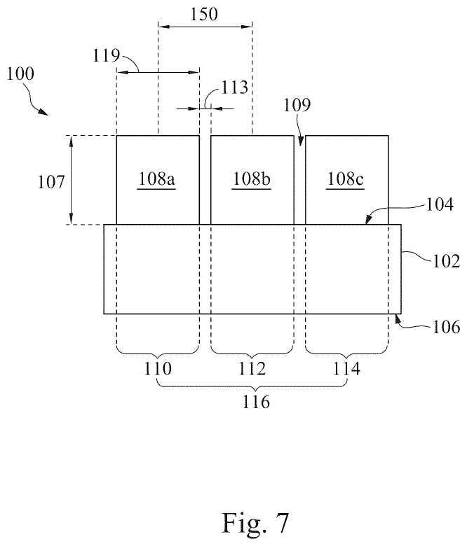

FIG. 7 is a schematic cross-sectional view of the image sensor device 100 taken along line A-A of FIG. 6. Photoresist columns 108a, 108b, and 108c define pixel regions for the image sensor device 100. For example, each of the photoresist columns 108a, 108b, and 108c defines a pixel region 110, 112, and 114, respectively, in the substrate 102. The pixel regions 110, 112, and 114 are regions where one or more pixels are to be formed. The pixel regions 110, 112, and 114 may be collectively referred to as a pixel array region 116. A logic region (not shown) is typically disposed outside the pixel array region 116. The photoresist columns have a resist pitch 150 that is a center-to-center distance between two immediately adjacent photoresist columns. The pixel region pitch of the pixel regions 110, 112, and 114 generally corresponds to the resist pitch 150 of the first photoresist columns 108a, 108b, 108c. The term “pixel region pitch” described herein refers to a center-to-center distance between two adjacent pixel regions. In cases where the grid-like pattern discussed above is used, the pixel region pitch of the pixel regions 110, 112, and 114 is less than about 1 μm. In some embodiments, the pixel region pitch and resist pitch 150 ranges from about 0.4 μm to about 1 μm.

Each of the first photoresist column 108a, 108b, 108c has a height 107 (i.e., vertical dimension) and a width 119 (i.e., lateral dimension). An aspect ratio of the first photoresist columns 108a, 108b, 108c is a ratio of the height 107 to the width 119. For a pixel size on the order of 1 micrometer, each of the first photoresist columns 108a, 108b, 108c may have an aspect ratio of about 3:1 to 1:1. In some embodiments, the aspect ratio of the first photoresist columns 108a, 108b, 108c is about 2:1. In an embodiment, each of the first photoresist columns 108a, 108b, 108c has an aspect ratio of about 1:1.

The first photoresist columns 108a, 108b, 108c are separated by a gap or trench 109. The trench 109 has a height that is equal to the height 107 of the first photoresist columns 108a, 108b, 108c, and a width 113. An aspect ratio of the trench 109 is a ratio of the height 107 to the width 113. The trench 109 has an aspect ratio of about 8:1 or greater. In some embodiments, the trench has an aspect ratio ranging from about 10:1 to about 30:1, an aspect ratio ranging from about 13:1 to about 25:1 in other embodiments, and an aspect ratio ranging from about 15:1 to about 20:1 in yet other embodiments. The aspect ratio of the first photoresist columns 108a, 108b, 108c is lower than the aspect ratio of the trench 109. In some embodiments, a ratio of the width 119 of each of the first photoresist columns 108a, 108b, 108c to the width 113 of the trench 109 is about 4:1 to about 30:1, about 6:1 to about 20:1 in other embodiments, and about 8:1 to about 10:1 in yet other embodiments.

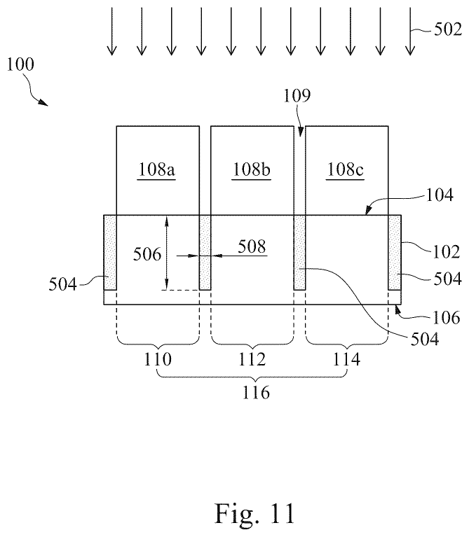

While the trench 109 has an ultrahigh aspect ratio of 8:1 or above, the lower aspect ratio of the first photoresist columns 108a, 108b, and 108c provide sufficient strength to the first photoresist columns 108a, 108b, and 108c to withstand the capillary forces inside the trench 109 without collapsing. Specifically, ultrahigh aspect ratio trench and lower aspect ratio of the first photoresist columns 108a, 108b, 108c result in the increased width 119 of each of the first photoresist columns 108a, 108b, 108c, which leads to good adhesion of the first photoresist columns 108a, 108b, 108c to the front side 104 of the device substrate 102. Therefore, the likelihood of the first photoresist columns 108a, 108b, and 108c collapsing is reduced as compared to those photoresist layers having ultrahigh aspect ratio photoresist columns and trench aspect ratios of 8:1 or greater. As a result, the first photoresist columns 108a, 108b, 108c can be formed taller and/or closer together (i.e., having a higher aspect ratio trench between the first photoresist columns 108a, 108b, 108c) without risking collapse of the first photoresist columns 108a, 108b, 108c. The combination of the lower aspect ratio of the first photoresist columns 108a, 108b, and 108c (such as about 3:1 or lower) and an ultrahigh aspect ratio trench (such as 8:1 or greater) are advantageous in performing subsequent fabrication processes such as formation of isolation regions by ion implantation, which will be discussed in greater detail below in FIG. 11.

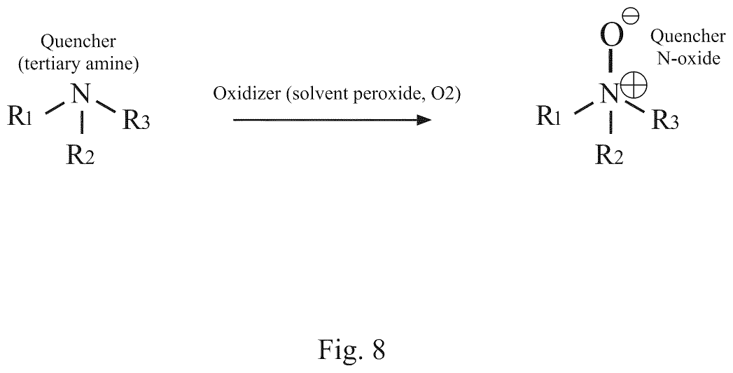

Byproduct contamination in the photoresist composition can cause resist pattern collapse or T-topping profiles in the photoresist pattern. For example, the quencher, such as a tertiary amine, in the photoresist composition may react with peroxides in the photoresist composition solvent or ambient oxygen to form tertiary amine oxides, as shown in FIG. 8. In some embodiments, the photoresist composition is analyzed by an analytical chemistry technique to determine the level of byproduct contamination. In some embodiments, the photoresist composition is analyzed using high performance liquid chromatography (HPLC) to determine the byproduct concentration. In some embodiments, a normalized concentration of the byproduct is determined by HPLC based on the peak area of the byproduct compared to the peak area of the other components of the photoresist composition (e.g.—polymer, photoactive compound, quencher, surfactant, and solvent).

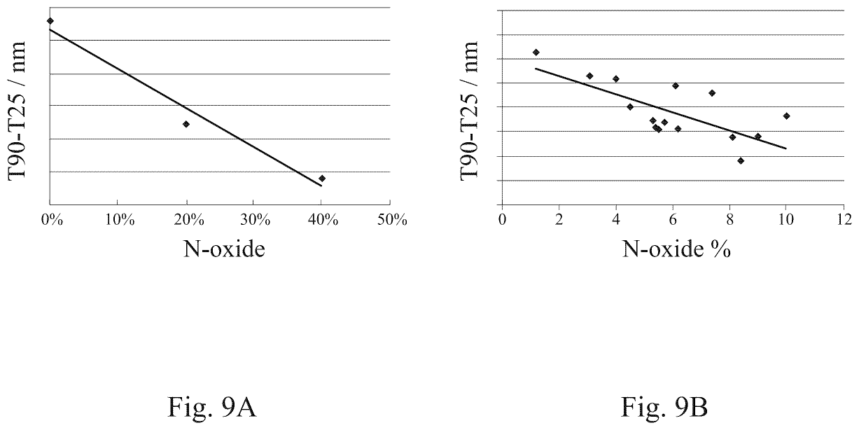

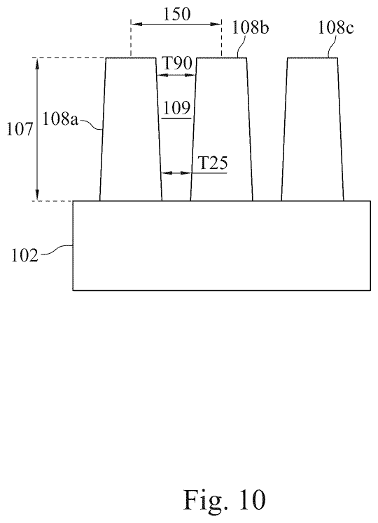

As shown in FIGS. 9A and 9B, the photoresist pattern profile can be controlled by tuning the byproduct concentration, such as the tertiary amine oxide (N-oxide) ratio. As shown in FIG. 9A, over an N-oxide normalized concentration range from about 40% to about 0%, the rate of change (slope) of the difference in a trench width of a photoresist trench 109 at 25% of the trench height (T25) 107 to the trench width at 90% of the trench height (T90) (T90−T25) is about −24 nm/normalized concentration % (see, FIG. 10). The N-oxide normalized concentration is the ratio of the peak area of the tertiary amine oxide determined by HPLC of the tertiary amine oxide to the peak area of the other components of the photoresist composition. However, as shown in FIG. 9B, at normalized N-oxide concentrations below about 10%, the rate of change (slope) of the difference in a trench width of a photoresist trench 109 at 25% of the trench height 107 to the trench width at 90% of the trench height (T90−T25) is about −0.7 nm/normalized concentration %. Thus, the slope of the difference in the trench width (T90−T25) is much lower at normalized N-oxide concentrations below about 10%. At normalized N-oxide concentration in the photoresist composition below about 10% photoresist pattern collapse and photoresist pattern profile T-topping is significantly reduced or eliminated compared to photoresist compositions having normalized tertiary amine oxide (N-oxide) concentrations greater than about 10%.

In embodiments of the disclosure, the photoresist composition is analyzed prior to forming the photoresist layer 108. If the concentration of the byproduct contaminants is below a threshold level, the photoresist composition is used for forming photoresist patterns with ultrahigh aspect ratios (e.g.—greater than 8:1). For example, if the byproduct contaminant is a tertiary amine oxide, the threshold level is a normalized concentration of about 10% in some embodiments.

In some embodiments, the byproduct contamination concentration is analyzed when a lot of photoresist composition is received, prepared, or prior to use in a photoresist dispensing operation. The photoresist composition may then be analyzed at periodic intervals to monitor the byproduct contaminant concentration level. If the byproduct contaminant concentration exceeds the threshold level the photoresist layer formation operation may be suspended, and the photoresist composition in a photoresist composition dispenser/reservoir is replaced with fresh photoresist composition having a byproduct contamination concentration below the threshold value. The periodic interval for analyzing the photoresist composition may be determined by empirical testing, and may vary depending on the specific composition of the photoresist.

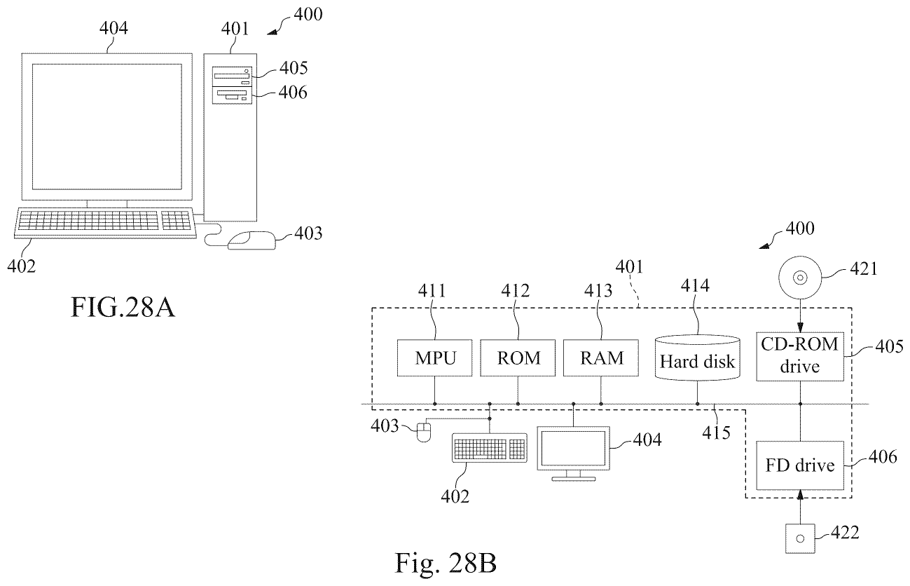

In some embodiments, sampling and analysis of the photoresist composition is automated. In the automated process, samples are drawn from the photoresist dispenser/reservoir at periodic intervals, the samples are introduced into an HPLC apparatus, and the normalized concentration of the byproduct contaminant is determined. A controller may generate an alarm if the concentration is above the threshold value or shut down the photoresist composition dispensing operation until the photoresist composition is replaced. A controller configured to control the automated sampling and analysis of the photoresist composition according to embodiments of the disclosure is described herein in further detail in reference to FIGS. 28A and 28B.

In some embodiments, when a photoresist composition is used having a byproduct contamination below the threshold level, the pattern formed has a width of the trench 109 at 90% of the trench height 107 from the substrate 102 (T90) ranging from about 250 nm to about 310 nm, and a width of the trench 109 at 25% of the trench height 107 from the substrate 102 (T25) ranging from about 200 nm to about 250 nm in a photoresist pattern having a pitch 150 of less than about 1 μm. In an embodiment, T90 is about 280 nm and T25 nm is about 225 nm. As shown in FIG. 10, in some embodiments, when the photoresist composition has a normalized concentration of tertiary amine oxide of below about 10% as determined by HPLC, the difference in the width of the photoresist trench 109 at T90 and T25 (T90−T25) ranges from about 40 nm to about 60 nm for a photoresist pattern having a pitch 150 of less than 1 μm. In some embodiments, the width of the photoresist trench at T25 ranges from about 0.75 to 0.90 of the width of the trench at T90.

After the first photolithography operation, the substrate 102 is subjected to additional processing operations, such as ion implantation or etching. In some embodiments, a first ion implantation process 502 is performed to form first isolation regions 504 in the substrate 102, as shown in FIG. 11. The first ion implantation process 502 is performed using the first photoresist columns 108a, 108b, and 108c as a mask to implant ions into regions of the device substrate 102 that are not protected by the first photoresist columns 108a, 108b, and 108c. The first isolation regions 504 isolate pixel regions 110, 112, and 114 from each other. The first isolation regions 504 prevent carriers at a specific pixel region from leaking into adjacent pixel region (also referred to as crosstalk). In some embodiments, the first isolation regions 504 exceed the depth of each pixel to be formed in the pixel regions 110, 112, 114. In some embodiments, the first isolation regions 504 extend from the front side 104 to the back side 106 of the device substrate 102 to provide a complete isolation well between the pixel regions 110, 112, and 114. Since the first photoresist columns 108a, 108b, and 108c are formed with a ultrahigh aspect ratio trench between the first photoresist columns 108a, 108b, and 108c, deeper isolation regions can be achieved with limited implant damages to the image sensor device (e.g., isolation regions can be formed with minimum lateral diffusion) even if high implantation energies are used. As a result, the ions can be implanted deeper to provide an effective pixel-to-pixel isolation for the image sensor device 100.

The first isolation regions 504 may be formed of p-type or n-type materials. The first isolation regions 504 may be formed with a material having the same doping polarity as the device substrate 100. In an embodiment, the first isolation regions 504 are p-type regions formed by implanting the device substrate 102 with p-type dopants such as boron, boron fluoride (BF₂), diborane (B₂H₆), or the like. The doping concentration of the first isolation regions 504 is in the range of about 5×10¹¹ atoms/cm³ to about 1×10²⁰ atoms/cm³ in some embodiments, and about 1×10¹² atoms/cm³ to about 5×10¹⁷ atoms/cm³ in other embodiments.

Each first isolation region 504 has a height 506 (vertical dimension) and a width 508 (lateral dimension). An aspect ratio of the first isolation region 504 is a ratio of the height 506 to the width 508. In some embodiments, the first isolation regions 504 have an aspect ratio of 10:1 or greater. In some embodiments, the aspect ratio ranges from about 12:1 to about 15:1.

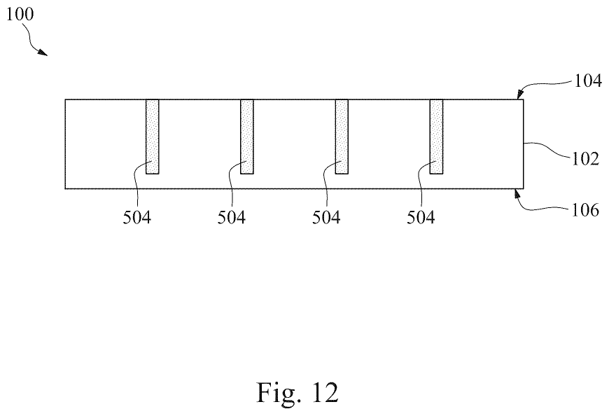

After the first isolation regions 504 have been formed, the first photoresist columns 108a-108i (i.e., first photoresist layer 108) are removed, for example, using a photoresist ashing or stripping process. FIG. 12 is a cross-sectional view of a portion of the image sensor device 100 after the first photoresist layer 108 has been removed.

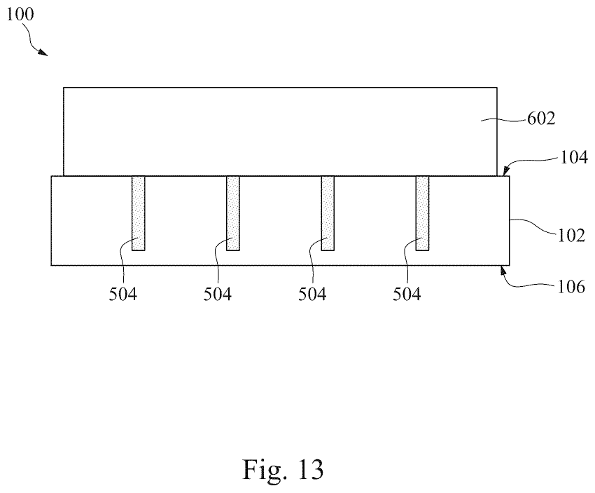

After the first photoresist layer 108 has been removed, a second photoresist layer 602 is formed over the front side 104 of the device substrate 102, as shown in FIG. 13. The second photoresist layer 602 may be formed by depositing a photoresist film over the front side 104 of the substrate 102 and thereafter patterning the photoresist film by a second photolithography process in the same manner as explained above with respect to FIGS. 2-7 using a photoresist composition having a concentration of byproduct contamination less than a threshold value. In some embodiments, the second lithography process used to pattern the second photoresist layer 602 is similar to the first lithography process used for the first photoresist layer 108 except that the second lithography process uses a second photomask, which has a pattern that is about half mask pitch offset from the first pattern 204 of the first photomask 202.

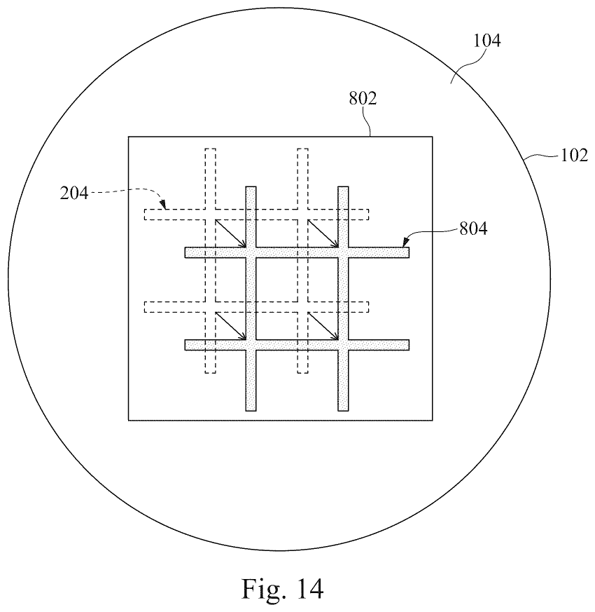

FIG. 14 is a schematic plan (top) view of a second photomask 802 having a second pattern 804 in accordance with an embodiment. The second photomask 802 is substantially identical to the first photomask 202 except that the second pattern 804 is diagonally shifted by half the mask pattern pitch from the first pattern 204. The first pattern 204 is depicted in dotted line for illustration purposes.

While a diagonal shift of the second pattern 804 is disclosed, the second pattern 804 may be offset by half the mask pattern pitch from the first pattern 204 in any desired direction such as in a lateral or vertical way to double the density of the isolation regions in the device substrate 102. The second pattern 804 is not limited to the grid-like pattern as shown. The second pattern 804 may be any other arrangements of patterns that provide second photoresist columns having a resist pitch of less than 1 μm.

While two different photomasks (i.e., first and second photomasks 202, 802) are disclosed to pattern the first and second photoresist layers 108, 602, respectively, it is contemplated that the first and second photolithography processes may use the same photomask to pattern the first and second photoresist layers 108, 602 by moving either the mask stage or the substrate stage to achieve the half mask pitch offset movement.

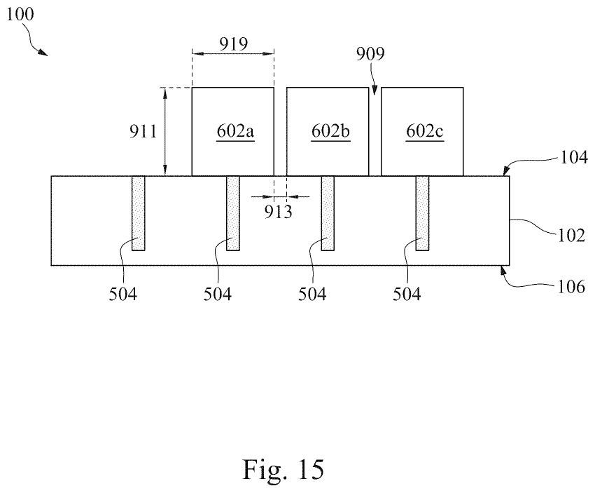

FIG. 15 illustrates a schematic cross-sectional view of a portion of the image sensor device 100 having a patterned second photoresist layer 602 on the substrate 102 in accordance with one embodiment. The second pattern in the second photoresist layer 602 includes photoresist columns 602a, 602b, 602c on the front side 104 of the substrate 102. While not shown, the patterned photoresist layer 602 has the grid-like pattern similar to the arrangement of the first photoresist columns 108a-108i shown in FIG. 6 except the second photoresist columns 602a, 602b, 602c are offset diagonally by half pitch from the first photoresist columns 108a-108i.

The second photoresist columns 602a, 602b, 602c are separated by a trench 909. The trench 909 has a height 911 (vertical dimension), which equals to the height of the second photoresist columns 602a, 602b, 602c, and a width 913 (lateral dimension). The photoresist columns 602a, 602b, 602c and the photoresist trenches 909 have the same heights 911, widths 919 and 913, as the respective heights 107, widths 119 and 113 as the photoresist columns 108a, 108b, 108c, and trenches 109 described in reference to FIG. 7.

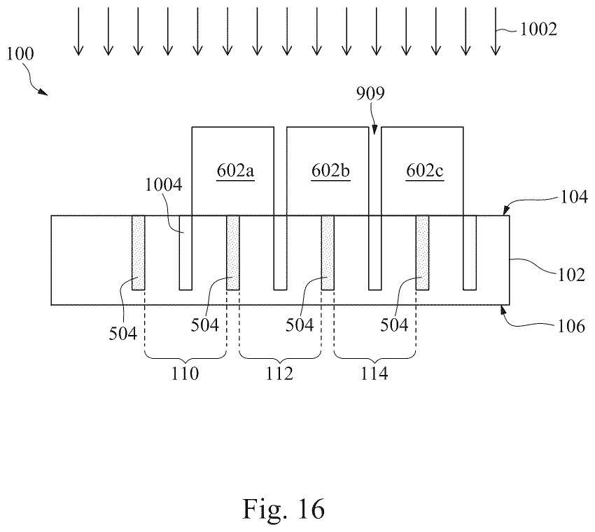

After the second photolithography operation, the substrate 102 is subjected to a second ion implantation process 1002 to form second isolation regions 1004 in the substrate 102 in some embodiments, as shown in FIG. 16. The second ion implantation process 1002 is performed using the second photoresist columns 602a, 602b, 602c as a mask to implant ions into regions of the device substrate 102 that are not protected by the second photoresist columns 602a, 602b, 602c. Since the second photoresist columns 602a, 602b, 602c are offset by half pitch from the first photoresist columns 108a-108i, the resulting second isolation regions 1004 will divide each of the pixel regions 110, 112, and 114 in half and isolate the divided pixel regions from each other. The second isolation regions 1004 prevent carriers at a specific pixel region to leak to adjacent pixel region. The second isolation regions 1004 may exceed the depth of each pixel to be formed in the divided pixel regions. In some embodiments, the second isolation regions 1004 may extend from the front side 104 to the back side 106 of the device substrate 102 to provide complete isolation well between the divided pixel regions. Since the second photoresist columns 602a, 602b, 602c are formed with an ultrahigh aspect ratio trench between the second photoresist columns 602a, 602b, 602c, deeper isolation regions can be achieved with limited implant damages to the image sensor device (e.g., isolation regions can be formed with minimum lateral diffusion) even if high implantation energies are used. As a result, the ions can be implanted deeper to provide an effective pixel-to-pixel isolation for the image sensor device 100.

The dopants, dopant concentration, and implant depth in the second ion implantation are the same as described herein with reference to FIG. 11 in some embodiments.

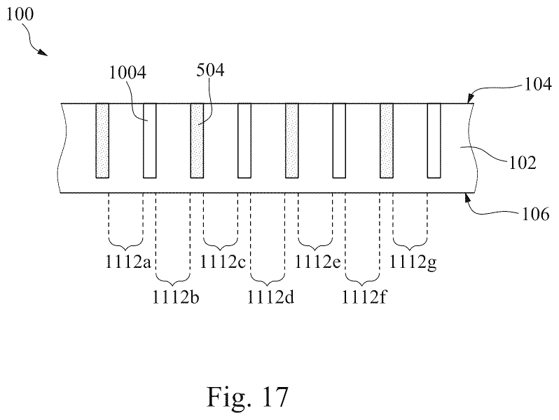

By performing two photolithography processes as described herein (i.e., two mask patterning process), the density of the pixel regions (such as pixel regions 1112a-1112g shown in FIG. 17) can be increased. The increased density of the pixel regions increases the resolution of the image sensor. The lithography processes according to an embodiment of the disclosure are performed using photoresist columns with an ultrahigh aspect ratio trench (e.g., greater than 8:1) without the risk of photoresist pattern collapsing.

After the second isolation regions 1004 have been formed, the second photoresist columns 602a, 602b, 602c are removed, for example, by using a photoresist ashing or stripping process. FIG. 17 illustrates a schematic cross-sectional view of the image sensor device 100 showing pixel regions, e.g., pixel regions 1112a-1112g, in the device substrate 102. The operations described above can be repeated to obtain a higher density of isolation regions at sub-micrometer pitches.

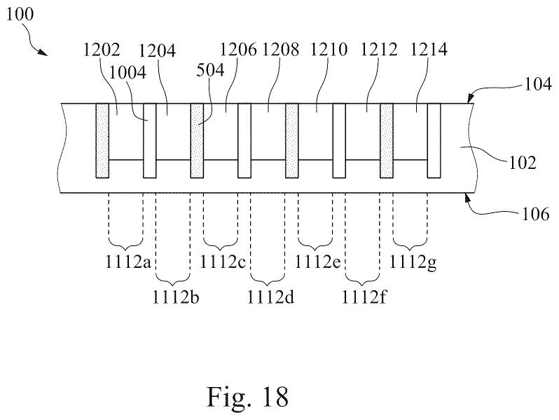

After the second photoresist columns 602a, 602b, 602c have been removed, a plurality of pixels 1202-1214 is formed in the pixel regions 1112a-1112g, respectively, as shown in FIG. 18. The pixels 1202-1214 may also be referred to as radiation-detection devices or light-sensors. The pixels 1202-1214 contain radiation-sensing regions. These radiation-sensing regions may be formed by one or more ion implantation processes and are doped with a doping polarity opposite from that of the substrate 102 and/or the first and second isolation regions 504, 1004. In cases where the device substrate 102 is p-type substrate, the pixels 1202-1214 contain n-type doped regions. For a BSI image sensor device such as the image sensor device 100, the pixels 1202-1214 are operable to detect radiation that is projected toward the device substrate 102 from the back side 106. In some embodiments, each of the pixels 1202-1214 includes a photodiode. A deep implant region is formed below each photodiode in some embodiments. In other embodiments, the pixels 1202-1214 each include pinned layer photodiodes, photogates, reset transistors, source follower transistors, and transfer transistors.

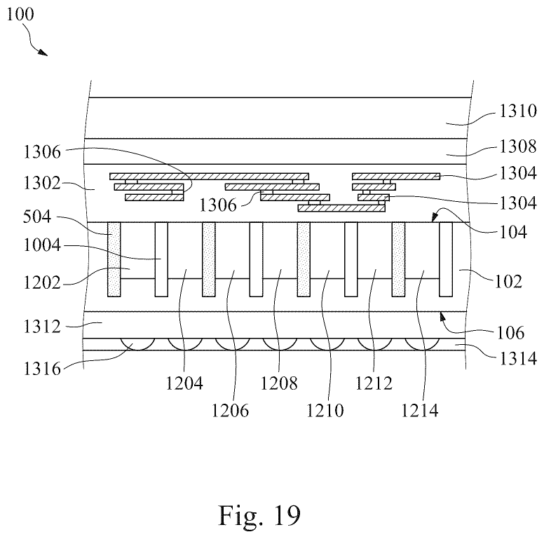

Additional fabrication processes may be performed to complete the fabrication of the image sensor device 100. For example, FIG. 19 illustrates an interconnect structure 1302 formed over the front side 104 of the substrate 102. The interconnect structure 1302 may include a plurality of patterned dielectric layers and conductive layers that provide interconnections between the various doped features, circuitry, and input/output of the image sensor device 100. The interconnect structure 1302 may include an interlayer dielectric (ILD) and a multilayer interconnect (MLI) structure. The MLI structure includes contacts, vias and metal lines. For purposes of illustration, a plurality of conductive lines 1304 and vias/contacts 1306 are shown in FIG. 13. The conductive lines 1304 and vias/contacts 1306 illustrated are merely exemplary as the actual positioning and configuration of the lines/vias/contacts may vary depending on design needs and manufacturing requirements.

A buffer layer 1308 may be formed on the interconnect structure 1302. The buffer layer 1308 may include a dielectric material such as silicon oxide or silicon nitride. Thereafter, a carrier substrate 1310 may be bonded with the device substrate 102 via the buffer layer 1308 so that processing of the back side 106 of the device substrate 102 can be performed. The carrier substrate 1310 may include a silicon substrate, a glass substrate, or any suitable substrate. The buffer layer 1308 provides electrical isolation between the device substrate 102 and the carrier substrate 1310. The carrier substrate 1310 provides support and mechanical strength for processing of the back side 106 of the device substrate 102.

After the carrier substrate 1310 is bonded, a thinning process is then performed to thin the device substrate 102 from the back side 106 in some embodiments. The thinning process may include a mechanical grinding process and a chemical thinning process. After the thinning process, a color filter layer 1312 may be formed on the back side 106 of the device substrate 102. The color filter layer 1312 may contain a plurality of color filters that may be positioned such that the incoming radiation is directed thereon and therethrough. The color filters may include a dye-based (or pigment based) polymer for filtering a specific wavelength band of the incoming radiation, which corresponds to a color spectrum (e.g., red, green, and blue). Thereafter, a micro-lens layer 1314 containing a plurality of micro-lenses 1316 is formed over the color filter layer 1312. The micro-lenses direct and focus the incoming radiation toward specific radiation-sensing regions in the device substrate 102, such as pixels 1202-1214. The micro-lenses may be positioned in various arrangements and have various shapes depending on a refractive index of a material used for the micro-lens and distance from a sensor surface.

In some embodiments, additional processing operations are performed on the substrate 102 while manufacturing a semiconductor device. For example, in some embodiments an etching operation is performed before or after the first or second ion implantation operations, or an etching operation may be performed instead of the first or second ion implantation operation.

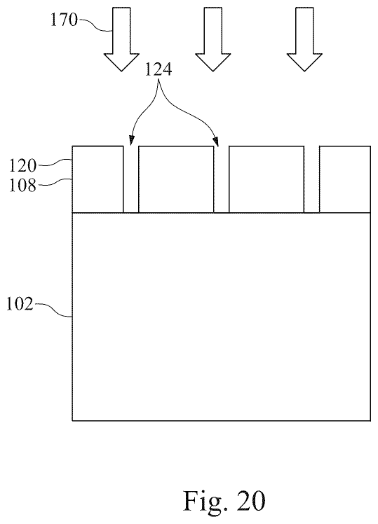

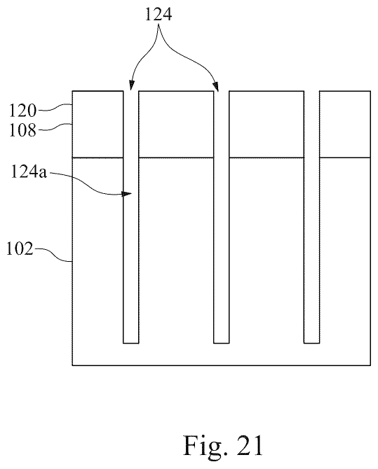

As shown in FIG. 20, an etching operation 170 is performed on the structure of FIG. 5, for example. The photoresist layer 108 is formed of a photoresist composition having a byproduct concentration below a threshold level, as described herein. The etching operation may include a dry (plasma) etching, a wet etching, and/or other etching methods. For example, a dry etching operation may implement an oxygen-containing gas, a fluorine-containing gas, a chlorine-containing gas, a bromine-containing gas, an iodine-containing gas, other suitable gases and/or plasmas, and/or combinations thereof. The etching operation 170 extends the trenches 124 in the photoresist layer 108 into the substrate 102 forming substrate trenches 124a, as shown in FIG. 21. The patterned photoresist layer 120 may be partially or completely consumed during the etching of the substrate 102.

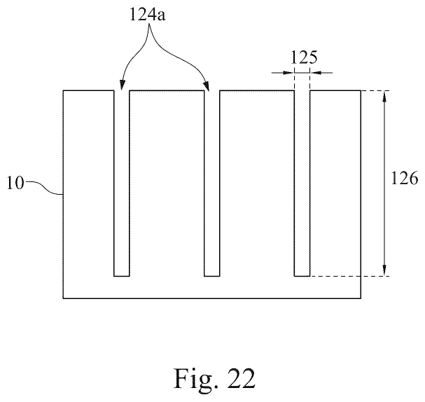

Any remaining portion of the patterned resist layer 120 is stripped off the substrate 102 using a suitable photoresist stripping technique, as shown in FIG. 22. The trenches 124a in the substrate have a width 125 and depth 126. In some embodiments, the substrate trenches 124a have an aspect ratio of the depth 126/width 125 of about 15 to about 60, and in other embodiments, the aspect ratio ranges from about 20 to about 50.

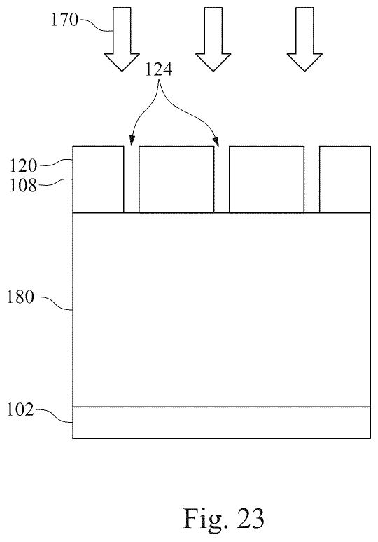

In some embodiments, a target layer 180 to be patterned is disposed over the substrate 102 prior to forming the photoresist layer 108, as shown in FIG. 23. In some embodiments, the target layer 180 is a metallization layer or a dielectric layer, such as a passivation layer, disposed over a metallization layer. In embodiments where the target layer 180 is a metallization layer, the target layer 180 is formed of a conductive material using metallization processes, and metal deposition techniques, including chemical vapor deposition, atomic layer deposition, and physical vapor deposition (sputtering). Likewise, if the target layer 180 is a dielectric layer, the target layer 180 is formed by suitable dielectric layer formation techniques, including thermal oxidation, chemical vapor deposition, atomic layer deposition, and physical vapor deposition.

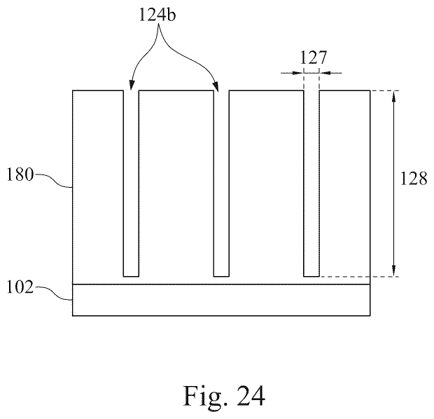

As shown in FIG. 23, an etching operation 170 is performed on the structure including a target layer 180 in some embodiments. The photoresist layer 108 is formed of a photoresist composition having a byproduct concentration below a threshold level, as described herein. The etching operation may include a dry (plasma) etching, a wet etching, and/or other etching methods. For example, a dry etching operation may implement an oxygen-containing gas, a fluorine-containing gas, a chlorine-containing gas, a bromine-containing gas, an iodine-containing gas, other suitable gases and/or plasmas, and/or combinations thereof. The etching operation 170 extends the trenches 124 in the photoresist layer 108 into the target layer 180 forming target layer trenches 124b, as shown in FIG. 24. The patterned photoresist layer 120 may be partially or completely consumed during the etching of the substrate 102.

Any remaining portion of the patterned resist layer 120 is stripped off the substrate 102 using a suitable photoresist stripping technique. The trenches 124b in the target layer 180 have a width 127 and depth 128. In some embodiments, the target layer trenches 124b have an aspect ratio of the depth 128/width 127 of about 15 to about 60, and in other embodiments, the aspect ratio ranges from about 20 to about 50.

It is understood that the sequence of the fabrication processes described above is not intended to be limiting. Some of the layers or devices may be formed according to different processing sequences in other embodiments than what is shown herein. While the above discussions pertain to a BSI image sensor device, it is contemplated that the various aspects of the present disclosure may be applied to a front side illuminated (FSI) image sensor device as well.

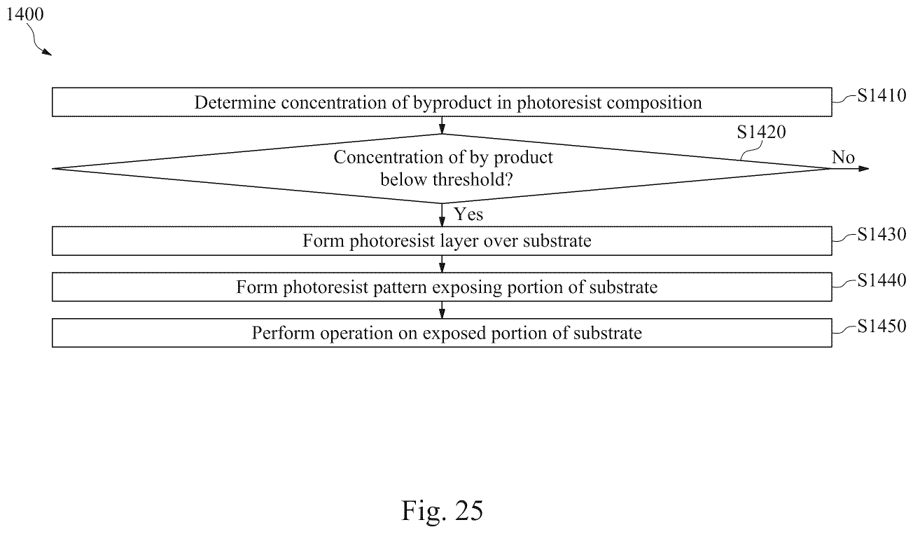

FIG. 25 is a flow chart illustrating a method 1400 of fabricating a semiconductor device. At operation S1410, a concentration of a byproduct in a photoresist composition is determined. If the concentration of the byproduct is below a threshold value at operation S1420 the photoresist composition is used to form a photoresist layer over a substrate at operation S1430. If the concentration of the byproduct exceeds the threshold value the photoresist composition may still be used in a semiconductor device manufacturing operation that produces photoresist patterns having lower aspect ratios than the aspect ratios required by the instant method. At operation S1440, a photoresist pattern exposing a portion of the substrate is formed. Then at operation S1450 an operation is performed on the exposed portion of the substrate. In an embodiment, the operation is an ion implantation operation or an etching operation.

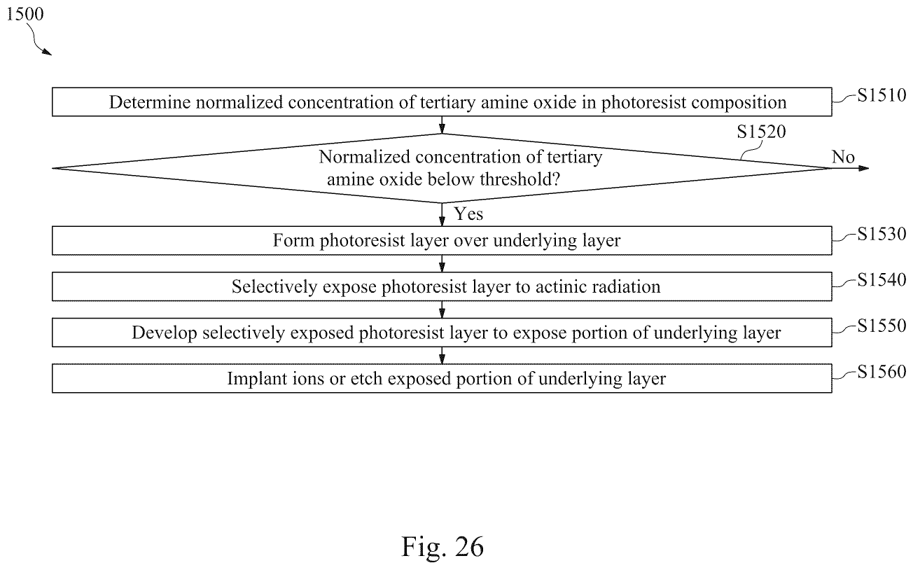

FIG. 26 is a flow chart illustrating a method 1500 of fabricating a semiconductor device. At operation S1510, a normalized concentration of a tertiary amine oxide in a photoresist composition is determined. If the concentration of the tertiary amine oxide is below a threshold value at operation S1520 the photoresist composition is used to form a photoresist layer over an underlying layer at operation S1530. In some embodiments, the underlying layer is a target layer 180 formed over a semiconductor substrate 102, in other embodiments, the target layer is the semiconductor substrate 102. If the concentration of the tertiary amine oxide exceeds the threshold value the photoresist composition may still be used in a semiconductor device manufacturing operation that produces photoresist patterns having lower aspect ratios than the aspect ratios required by the instant method. The photoresist layer is selectively exposed to actinic radiation to form a latent pattern at operation S1540. The selectively exposed photoresist layer is then developed to form a photoresist pattern exposing a portion of the underlying layer at operation S1550. At operation S1560, ions are implanted in the exposed portion of the underlying layer or the exposed portion of the underlying layer are etched.

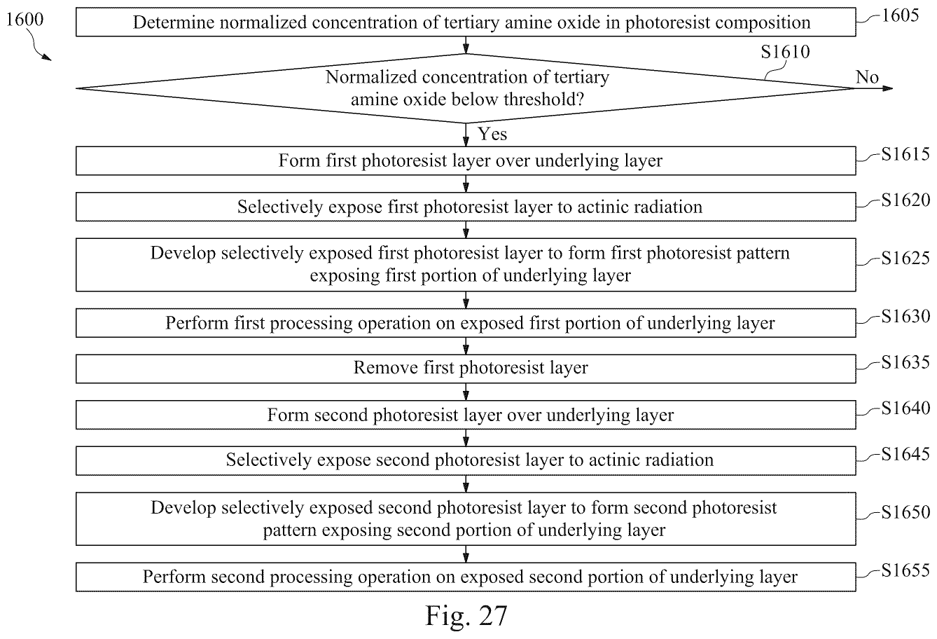

FIG. 27 is a flowchart illustrating a method 1600 of manufacturing a complementary metal-oxide-semiconductor image sensor. At operation S1605, a normalized concentration of a tertiary amine oxide in a photoresist composition is determined. If the concentration of the tertiary amine oxide is below a threshold value at operation S1610 the photoresist composition is used to form a photoresist layer over an underlying layer at operation S1615. In some embodiments, the underlying layer is a target layer 180 formed over a semiconductor substrate 102, in other embodiments, the target layer is the semiconductor substrate 102. If the concentration of the tertiary amine oxide exceeds the threshold value the photoresist composition may still be used in a semiconductor device manufacturing operation that produces photoresist patterns having lower aspect ratios than the aspect ratios required by the instant method. The first photoresist layer is selectively exposed to actinic radiation to form a first latent pattern at operation S1620. The selectively exposed first photoresist layer is developed to form a first photoresist pattern exposing a first portion of the underlying layer at operation S1625. At operation S1630, a first processing operation is performed on the exposed first portion of the underlying layer. In some embodiments, the first processing operation is ion implantation or etching. Then, at operation S1635, the first photoresist layer is removed. A second photoresist layer is subsequently formed over the underlying layer using the photoresist composition at operation S1640, and the second photoresist layer is selectively exposed to actinic radiation to form a second latent pattern at operation S1645. The selectively exposed second photoresist layer is developed at operation S1650 to form a second photoresist pattern exposing a second portion of the underlying layer. In some embodiments, the second portion of the underlying layer is a different portion of the underlying layer than the first portion of the underlying layer. At operation S1655, a second processing operation is performed on the exposed second portion of the underlying layer, wherein the second processing operation is a different operation than the first processing operation. In some embodiments, the second processing operation is ion implantation or etching.

In some of the disclosed embodiments, all of or a part of the methods or operations are realized using computer hardware and special purpose computer programs executed thereon. In FIG. 28A, an embodiment of the controller 400 is illustrated. The controller 400 is a computer system 400 provided with a computer 401 including an optical disk read only memory (e.g., CD-ROM or DVD-ROM) drive 405 and a magnetic disk drive 406, a keyboard 402, a mouse 403, and a monitor 404 in some embodiments.

FIG. 28B is a diagram showing an internal configuration of the computer system 400 in some embodiments. In FIG. 28B, the computer 401 is provided with, in addition to the optical disk drive 405 and the magnetic disk drive 406, one or more processors 411, such as a micro-processor unit (MPU); a ROM 412 in which a program such as a boot up program is stored; a random access memory (RAM) 413 connected to the processors 411 and in which a command of an application program is temporarily stored and a temporary electronic storage area is provided; a hard disk 414 in which an application program, an operating system program, and data are stored; and a data communication bus 415 that connects the processors 411, the ROM 412, and the like. Note that the computer 401 may include a network card (not shown) for providing a connection to a computer network such as a local area network (LAN), wide area network (WAN) or any other useful computer network for communicating data used by the computing system 400.

The program for causing the computer system 400 to execute the process for controlling the byproduct sampling and analysis and/or to execute any of the other operations in the method of manufacturing a semiconductor device according to the embodiments disclosed herein are stored in an optical disk 421 or a magnetic disk 422, which are inserted into the optical disk drive 405 or the magnetic disk drive 406, and transmitted to the hard disk 414. Alternatively, the program may be transmitted via a network (not shown) to the computer system 400 and stored in the hard disk 414. At the time of execution, the program is loaded into the RAM 413. The program may be loaded from the optical disk 421 or the magnetic disk 422, or directly from a network. The stored programs do not necessarily have to include, for example, an operating system (OS) or a third-party program to cause the computer 401 to execute the methods disclosed herein. The program includes a command portion to call an appropriate function (module) in a controlled mode and obtain desired results in some embodiments.

In some embodiments, a shrinkage material may be optionally applied to first and second photoresist columns 108a-108c and 602a-602c shown in FIGS. 7 and 15, respectively, to further prevent collapsing of photoresist columns due to capillary forces. The shrinkage material may be produced by mixing surfactant particles uniformly in a chemical material. The surfactant particles include compounds or molecules that lower the surface tension between liquids or between a liquid and a solid. For example, a surfactant particle includes a molecule having one end that is water-soluble and an opposite end that is oil-soluble. The surfactant molecules may aggregate to form micelles. In some embodiments, each of the surfactant particles includes a fluorinated compound. In some other embodiments, the surfactant particles include a hydrocarbon compound.

In some embodiments, the chemical material includes a “resolution enhancement lithography assisted by chemical shrinkage” material (or RELACS). The RELACS material includes a water-soluble material (e.g., a polymer) having thermal cross-linking properties. As examples, the details of the RELACS material are discussed in an article entitled “Resists Join the Sub-Lambda Revolution,” by Laura J. Peters, published in Semiconductor International, in September, 1999, as well as in Japanese Patent Application KOKAI publication No. H10-73927, the contents of each of which are hereby incorporated by reference in their respective entireties.

In another embodiment, the chemical material includes a “shrink assist film for enhanced resolution” material (or SAFIER) developed by Tokyo Ohka Kogyo Co. The SAFIER material includes an aqueous solution that contains thermo-responsive polymers that facilitate photoresist flow during a baking process. As an example, the details of the SAFIER material are discussed in a paper entitled “Electron-beam SAFIER™ process and its application for magnetic thin-film heads,” by XiaoMin Yang, et al., published in the Journal of Vacuum Science & Technology B, Volume 22, Issue 6, in December 2004, the contents of which are hereby incorporated by reference in its entirety.

Embodiments of the present disclosure provide ultrahigh aspect ratio photoresist patterns for forming semiconductor devices, such as CMOS image sensors (CIS). Embodiments of the present disclosure provide methods for manufacturing CIS with pixel sizes ranging from about 0.4 μm to about 1 μm. Selecting photoresists compositions having byproduct contamination concentrations below a threshold value according to the present disclosure significantly reduce or eliminate photoresist pattern collapse and photoresist pattern profile T-topping. Embodiments of the present disclosure, enable the formation of ultrahigh (>8:1) aspect ratio photoresist patterns and substrate trenches having aspect ratios of up to 60:1 without etch residues forming on the sidewalls of bottoms of the trenches. Embodiments of the disclosure prevent the formation of white pixel images in the CIS sensor caused by photoresist pattern collapse. Embodiments of the disclosure provide an economical and efficient solution to photoresist pattern collapse and etch residue issues encountered when forming ultrahigh aspect ratio photoresist patterns.

An embodiment of the disclosure is a method of fabricating a semiconductor device, including determining a concentration of a byproduct in a photoresist composition. A photoresist layer is formed over a substrate using the photoresist composition when the concentration of the byproduct is below a threshold value. A photoresist pattern is formed in the photoresist layer exposing a portion of the substrate, and an operation is performed on the exposed portion of the substrate. In an embodiment, the operation is an ion implantation operation. In an embodiment, the operation is an etching operation. In an embodiment, the etching operation forms a trench in the substrate having an aspect ratio of 15 to 60. In an embodiment, the byproduct is a tertiary amine oxide. In an embodiment, a normalized concentration of the tertiary amine oxide is less than 10% based on a total concentration of the photoresist composition as determined by high performance liquid chromatography. In an embodiment, a trench in the photoresist pattern has an aspect ratio ranging from 8 to 30. In an embodiment, a width of the trench in the photoresist pattern at 25% of a trench height from the substrate ranges from 0.75 to 0.90 of a width of the trench at 90% of the trench height from the substrate. In an embodiment, the semiconductor device is a complementary metal-oxide-semiconductor image sensor.

Another embodiment of the disclosure is a method of fabricating a semiconductor device, including determining a normalized concentration of a tertiary amine oxide in a photoresist composition. A photoresist layer is formed over an underlying layer using the photoresist composition when the normalized concentration of the tertiary amine oxide is below a threshold value. The photoresist layer is selectively exposed to actinic radiation to form a latent pattern. The selectively exposed photoresist layer is developed to form a photoresist pattern exposing a portion of the underlying layer. Ions are implanted in the exposed portion of the underlying layer or the exposed portion of the underlying layer are etched. In an embodiment, the underlying layer is a semiconductor substrate or a target layer disposed over a semiconductor substrate. In an embodiment, the underlying layer is etched forming a trench in the underlying layer having an aspect ratio of 15 to 60. In an embodiment, the normalized concentration of the tertiary amine oxide is less than 10% based on a total concentration of the photoresist composition as determined by high performance liquid chromatography. In an embodiment, a trench in the photoresist pattern has an aspect ratio ranging from 8 to 30. In an embodiment, a width of the trench in the photoresist pattern at 25% of a trench height from the underlying layer ranges from 0.75 to 0.90 of a width of the trench at 90% of the trench height from the underlying layer. In an embodiment, the photoresist pattern has a pitch of less than 1 μm.

Another embodiment of the disclosure is a method of manufacturing a complementary metal-oxide-semiconductor image sensor, including determining a normalized concentration of a tertiary amine oxide in a photoresist composition. A first photoresist layer is formed over an underlying layer using the photoresist composition when a concentration of the tertiary amine oxide is below a threshold value. The first photoresist layer is selectively exposed to actinic radiation to form a first latent pattern. The selectively exposed first photoresist layer is developed to form a first photoresist pattern exposing a first portion of the underlying layer. A first processing operation is performed on the exposed first portion of the underlying layer. The first photoresist layer is removed. A second photoresist layer is formed over the underlying layer using the photoresist composition. The second photoresist layer is selectively exposed to actinic radiation to form a second latent pattern. The selectively exposed second photoresist layer is developed to form a second photoresist pattern exposing a second portion of the underlying layer. The second portion of the underlying layer is a different portion of the underlying layer than the first portion of the underlying layer. A second processing operation is performed on the exposed second portion of the underlying layer, wherein the second processing operation is a different operation than the first processing operation. In an embodiment, the first processing operation is ion implantation and the second processing operation is etching. In an embodiment, the first processing operation is etching and the second operation is ion implantation. In an embodiment, the actinic radiation is deep ultraviolet radiation.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
determining a normalized concentration of a tertiary amine oxide in a photoresist composition;
forming a first photoresist layer over an underlying layer using the photoresist composition when a concentration of the tertiary amine oxide is below a threshold value;
selectively exposing the first photoresist layer to actinic radiation to form a first latent pattern;
developing the selectively exposed first photoresist layer to form a first photoresist pattern exposing a first portion of the underlying layer;
performing a first processing operation on the exposed first portion of the underlying layer;
removing the first photoresist layer;
forming a second photoresist layer over the underlying layer using the photoresist composition;
selectively exposing the second photoresist layer to actinic radiation to form a second latent pattern;
developing the selectively exposed second photoresist layer to form a second photoresist pattern exposing a second portion of the underlying layer,
wherein the second portion of the underlying layer is a different portion of the underlying layer than the first portion of the underlying layer; and
performing a second processing operation on the exposed second portion of the underlying layer,
wherein the second processing operation is a different operation than the first processing operation.

2. The method of claim 1, wherein the first processing operation is ion implantation and the second processing operation is etching.

3. The method of claim 2, wherein the etching operation forms a trench in the underlying layer having an aspect ratio of 15 to 60.

4. The method of claim 1, wherein the first processing operation is etching and the second operation is ion implantation.

5. The method of claim 4, wherein the etching operation forms a trench in the underlying layer having an aspect ratio of 15 to 60.

6. The method of claim 1, wherein the actinic radiation is deep ultraviolet radiation.

7. The method of claim 1, wherein the threshold value of the normalized concentration of the tertiary amine oxide is less than 10% based on a total concentration of the photoresist composition as determined by high performance liquid chromatography.

8. The method of claim 7, wherein a width of a trench in the first photoresist pattern or the second photoresist pattern at 25% of a trench height from the underlying layer ranges from 0.75 to 0.90 of a width of the trench at 90% of the trench height from the underlying layer.

9. The method of claim 1, wherein the semiconductor device is a complementary metal-oxide-semiconductor image sensor.

10. A method of fabricating a semiconductor device, comprising:
determining a concentration of a tertiary amine oxide byproduct in a photoresist composition;
forming a first photoresist layer over a substrate using the photoresist composition when the concentration of the tertiary amine oxide byproduct is below a threshold value;
forming a first photoresist pattern in the first photoresist layer exposing a first portion of the substrate;
performing a first processing operation on the exposed first portion of the substrate;
removing the first photoresist layer;
forming a second photoresist layer over the substrate using the photoresist composition;
forming a second photoresist pattern in the second photoresist layer exposing a second portion of the substrate; and
performing a second processing operation on the exposed second portion of the substrate,
wherein the first processing operation and the second processing operation are different.

11. The method of claim 10, wherein the second portion of the substrate is a different than the first portion of the substrate.

12. The method of claim 10, wherein the first processing operation and the second processing operation are independently selected from an etching operation or an ion implantation operation.

13. The method of claim 12, wherein the etching operation forms a trench in the substrate having an aspect ratio of 15 to 60.

14. The method of claim 13, wherein a normalized concentration of the tertiary amine oxide is less than 10% based on a total concentration of the photoresist composition as determined by high performance liquid chromatography.

15. The method of claim 12, wherein a trench in the photoresist pattern has an aspect ratio ranging from 8 to 30.

16. The method of claim 15, wherein a width of the trench in the photoresist pattern at 25% of a trench height from the substrate ranges from 0.75 to 0.90 of a width of the trench at 90% of the trench height from the substrate.

17. A method of fabricating a semiconductor device, the method comprising:
determining a normalized concentration of a tertiary amine oxide in a photoresist composition;
forming a first photoresist layer over an underlying layer using the photoresist composition when the normalized concentration of the tertiary amine oxide is below a threshold value;
selectively exposing the first photoresist layer to actinic radiation to form a latent pattern;
developing the selectively exposed first photoresist layer to form a first photoresist pattern exposing a first portion of the underlying layer;
performing a first processing operation selected from one of an ion implantation operation to implant ions in the exposed first portion of the underlying layer or an etching operation to etch the exposed first portion of the underlying layer;
removing the first photoresist layer;
forming a second photoresist layer over the underlying layer using the photoresist composition;
selectively exposing the second photoresist layer to actinic radiation to form a latent pattern;
developing the selectively exposed second photoresist layer to form a second photoresist pattern exposing a second portion of the underlying layer; and
performing a second processing operation selected from one of an ion implantation operation to implant ions in the exposed second portion of the underlying layer or an etching operation to etch the exposed first portion of the underlying layer,
wherein the second processing operation is different than the first processing operation.

18. The method of claim 17, wherein the underlying layer is a semiconductor substrate or a target layer disposed over a semiconductor substrate.

19. The method of claim 17, wherein the normalized concentration of the tertiary amine oxide is less than 10% based on a total concentration of the photoresist composition as determined by high performance liquid chromatography.

20. The method of claim 17, wherein a width of a trench in the photoresist pattern at 25% of a trench height from the underlying layer ranges from 0.75 to 0.90 of a width of the trench at 90% of the trench height from the underlying layer.
